(19) United States
(12) Patent Application Publication
(10) Pub. No.: US 2025/0224438 A1
(43) Pub. Date: Jul. 10, 2025

(54) TESTING SEMICONDUCTOR MODULES

(71) Applicant: SAMSUNG ELECTRONICS CO., LTD., Suwon-si (KR)

(72) Inventors: Sunhee Kim, Suwon-si (KR); Suk Hyun, Suwon-si (KR)

(21) Appl. No.: 18/937,987

(22) Filed: Nov. 5, 2024

(30) Foreign Application Priority Data
Jan. 4, 2024 (KR) 10-2024-0001554

(51) Int. Cl. G01R 31/26; G01R 31/28

(52) U.S. Cl. CPC G01R 31/2601; G01R 31/2867; G01R 31/287

(57) ABSTRACT

A method includes receiving test information, matching test program data and board data stored in a database to the test information, simulating loading of the semiconductor module based on a result of the matching, selecting at least one target slot from among slots of a board based on a result of the simulating, picking the semiconductor module to correspond to the number of at least one target slot using a plurality of hands of a gripper, and loading the semiconductor module to at least one target slot of the board.

### CROSS-REFERENCE TO RELATED APPLICATION

This application claims priority under 35 U.S.C. § 119 to Korean Patent Application No. 10-2024-0001554, filed on Jan. 4, 2024, in the Korean Intellectual Property Office, the entirety of which is incorporated by reference herein.

### BACKGROUND

After semiconductor devices are manufactured, a test process is performed on the semiconductor devices to determine whether the products are defective. As semiconductor technology becomes more advanced and semiconductor devices become more complex, the process of testing products is also becoming more complicated. Therefore, the test environment varies depending on the board, test program, semiconductor module, and the like, which are used in the test process.

### SUMMARY

Some implementations according to this disclosure provide test methods and test devices for automating tests of semiconductor devices, to reduce the cost and time required by automating a loading operation of semiconductor modules.

According to some implementations, there is provided a method of testing a semiconductor module, the method including receiving test information, matching test program data and board data stored in a database to the test information, simulating loading of the semiconductor module based on a result of the matching, selecting at least one target slot from among slots of a board based on a result of the simulating, picking the semiconductor module to correspond to the number of at least one target slot using a plurality of hands of a gripper, and loading the semiconductor module to the at least one selected target slot of the board.

According to some implementations, there is provided a device for testing a semiconductor module, the device including at least one processor, and a memory including a database in which test program data and board data are stored, wherein the at least one processor is configured to match the received test information to the test program data and the board data, simulate loading of the semiconductor module based on a result of the matching, select at least one target slot from among slots of a board based on a result of the simulating, control a gripper of the device based on the at least one target slot, pick the semiconductor module to correspond to the number of at least one target slot, using a plurality of hands of the gripper, and load the semiconductor module in the at least one target slot of the board.

According to some implementations, there is provided a method of loading a semiconductor module, the method including receiving the type data of a target board on which the semiconductor module is to be loaded, matching board data to the type data, in which the board data includes location information on slots according to the structure of a board, stored in a database, selecting at least one target slot among slots of the target board based on the result of the matching, generating slot data including information about the at least one target slot, controlling, based on the slot data, a gripper including a plurality of hands, and loading the semiconductor module to the at least one target slot of the target board through the gripper.

### BRIEF DESCRIPTION OF THE DRAWINGS

Implementations according to the present disclosure will be more clearly understood from the following detailed description taken in conjunction with the accompanying drawings in which:

FIG. 1 is a block diagram schematically illustrating an example of a test device;

FIG. 2 is a flowchart illustrating an example of a test method;

FIG. 3 is a diagram illustrating an example of a matching process;

FIG. 4 is a flowchart illustrating an example of a simulation operation;

FIG. 5 is a diagram illustrating an example of a simulation operation;

FIG. 6 is a flowchart illustrating an example of a method of selecting a target slot;

FIGS. 7A and 7B are diagrams illustrating examples of selection of a target slot;

FIG. 8 is a flowchart illustrating an example of a method of determining a target slot;

FIG. 9 is a diagram illustrating an example of target slot determination;

FIG. 10 illustrates side views of an example of a gripper;

FIGS. 11A and 11B are front views of an example of a gripper; and

FIG. 12 is a block diagram illustrating an example of a test system.

### DETAILED DESCRIPTION

Hereinafter, examples will be described in detail with reference to the accompanying drawings.

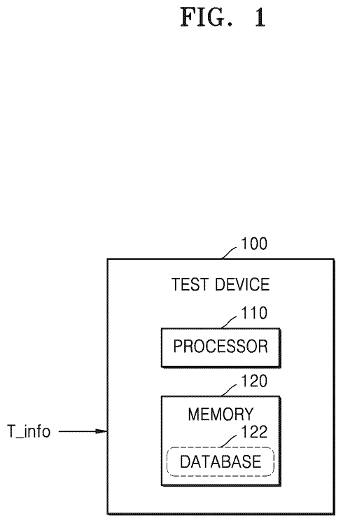

FIG. 1 is a block diagram schematically illustrating a test device according to some implementations of the present disclosure.

Referring to FIG. 1, a test device 100 may include a processor 110 and a memory 120. The test device 100 may be a device that performs a test operation by loading a semiconductor module on a board. For example, a test process may be performed to check whether mass-produced modules operate in an actual-use environment, and the test device 100 may perform the test process by loading the mass-produced modules on a device (e.g., a board). Here, the modules may be referred to as semiconductor modules or memory modules; it will be understood that the scope of the modules as described herein is not limited to memory modules.

A board (e.g., a motherboard) on which semiconductor modules are to be loaded may be mounted in the test device 100, and a test may be performed by loading the semiconductor modules on the board, e.g., the semiconductor modules may be tested while loaded on the board. In this case, the same type (or model, kind, etc.) of board is not always used, and other types of boards may be mounted on the test device 100. In some implementations, even if various types of boards are used, the test device 100 may facilitate semiconductor modules to be loaded onto the various types of boards, as described below.

The test device 100 may receive test information T_info from the outside, e.g., from an external device. The test information T_info may be information including specific test content for use when the test device 100 performs a test. For example, the test information T_info may include data on, of, or indicating a test program to be executed by loading a semiconductor module in the test device 100. The test program may be implemented in various ways according to the purpose and content of the test. Conditions under which semiconductor modules are loaded on a board may vary depending on the test program. For example, a first test program may be aimed at testing to evaluate the timing characteristics of semiconductor modules, and a second test program may be aimed at testing to evaluate the speed performance of the semiconductor modules. Various conditions (e.g., the number of semiconductor modules loaded in slots, the locations of the slots, etc.) for loading semiconductor modules in slots of a board in order to perform the first test program may vary in different implementations.

In addition, the test information T_info may include information about a board. The information about a board may be data on the type (or model or kind) of the board on which the semiconductor module is to be loaded. The configuration and structure of the board and locations and/or arrangement of slot(s) of the board may vary according to the type of the board. The test information T_info may include data on the type of board to be mounted on the test device 100 for testing, among various board types.

The processor 110 may perform a matching operation based on the received test information T_info. The memory 120 may include a database 122. Data for various test programs may be stored in the database 122, and data for types of various boards may be stored in the database 122. In some implementations, the processor 110 may match the received test information T_info to the test program data and the board data stored in the database 112 included in the memory 120. Through the matching operation, the processor 110 may determine a loading condition based on test program data corresponding to the test information T_info and the type of the board corresponding to the test information T_info and may select a target slot in which the semiconductor module is loaded from among the slots of the board based on a result of the matching.

The processor 110 may test the semiconductor module loaded on the board by performing a series of processes (or programs) associated with the test operation. For example, the processor 110 may generate a test signal to test the semiconductor module loaded in a slot of a board and may examine an output signal generated from the semiconductor module based on the test signal to determine the state and/or performance of the semiconductor module. The test signal may include any suitable signal used in the semiconductor module to be tested and may include logic value information for testing logic, a test signal to obtain power information of a memory, a test signal to obtain information on the operating temperature of the semiconductor module, and/or a test signal to obtain information on Signal Integrity (SI) and Power Integrity (PI). The test signal may be configured in various ways based on the test program (e.g., may have a configuration corresponding to the test program), and the processor 110 may select a target slot in which the semiconductor module is to be loaded based on a loading condition determined according to the matching of the test information T_info to the test program data stored in the database 122.

It will be understood that, in some implementations, the test device 100 includes other components for testing semiconductor modules.

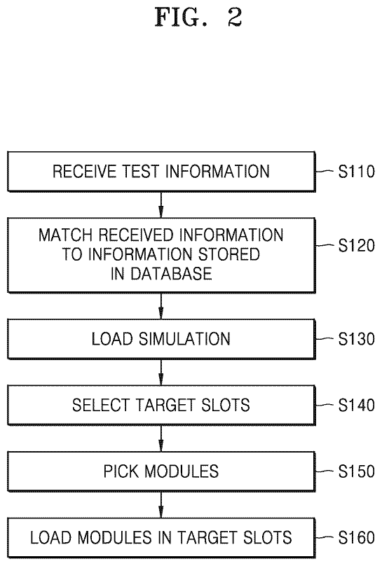

FIG. 2 is a flowchart illustrating a test method according to some implementations. The test method may include a plurality of operations S110 to S160. The test method can be performed by a test device such as the test device 100 of FIG. 1.

In operation S110, the test device 100 receives test information T_info. The test information T_info may include information characterizing the board on which the semiconductor module is to be loaded and may include test program data, which is information characterizing a program to be executed by the test device 100 to test the semiconductor module loaded on the board. The processor 110 of the test device 100 may perform a test operation based on the test program data to obtain a test result (e.g., information on the operating temperature of the semiconductor module, timing information, data processing speed information, and/or information on SI and/or PI). A condition in which the semiconductor module is loaded on the board (a loading condition) may vary based on the test program data.

In operation S120, the processor 110 matches the received test information T_info to test program data and board data stored in the database 122 included in the memory 120. For example, the processor 110 may obtain, using a matching operation, information on a test program to be executed by the test device 100 from the database 122 and information on a board on which the semiconductor module is to be loaded. The processor 110 may determine the loading condition based on the matching result (the information).

In operation S130, the processor 110 performs a loading simulation based on the loading condition. In some implementations, the simulation may be an operation of classifying or selecting slots of a board based on the loading condition.

In operation S140, the processor 110 selects a target slot in which the semiconductor module is to be loaded, based on a result of the simulating. In some implementations, the semiconductor module may be loaded and tested only in one or more of the slots of the board (e.g., a subset of the slots) based on the loading conditions, and the processor 110 may select a target slot in which the semiconductor module is actually loaded from among the slots of the board.

In operation S150, the processor 110 picks the semiconductor module by controlling a gripper of the test device 100 to load the semiconductor module in the selected target slot. In some implementations, the processor 110 picks a number of semiconductor modules, using the gripper, that corresponds to the number of target slots selected by the processor 110 as a result of the simulating. The gripper may include a plurality of hands for picking the semiconductor modules. The gripper may transfer the semiconductor modules picked by the plurality of hands to the test device 100 to be loaded on a board mounted on the test device 100. In some implementations, each of the plurality of hands may be individually controlled, and the gripper may arrange the plurality of hands at pitches that allow the plurality of hands to load the picked semiconductor modules in each target slot. For example, the spacing between the plurality of hands may vary, and the gripper may control the spacing between the plurality of hands to correspond to the location of each of the target slots. In operation S150, the gripper may load, into each target slot, semiconductor modules held by the plurality of hands pitched to correspond to the locations of the target slots.

Accordingly, the test device 100 and the test method of FIG. 2 may automate the process of loading a semiconductor module onto the board. The conditions under which the semiconductor module is loaded and/or the location of the slot in which the semiconductor module is loaded may vary depending on the test program and the type of the board, and the test device 100 may load the semiconductor module in correspondence thereto. Since the loading operation of the semiconductor module is not performed manually, the loading operation may be automated through the test device 100 and the test method. Accordingly, in some implementations, the time and cost consumed in loading may be reduced compared to manual loading, and loading reliability and/or quality may be improved, for example, by reducing or preventing damage to the semiconductor module that may occur in manual operation.

In addition, in some implementations the test device 100 and the test method of FIG. 2 are be flexibly responsive to various programs and board types, for example, based on the use of the database 122 storing program data and board data. For example, although the loading conditions may vary depending on the test program, and the location or arrangement of the slots may vary depending on the type of board, the test device 100 and the test method can be adapted to those process variables.

Furthermore, in some implementations, the test device 100 and the test method may incorporate simultaneous loading operations of multiple semiconductor modules through a gripper with an adjustable pitching interval between hands, thereby improving operation efficiency.

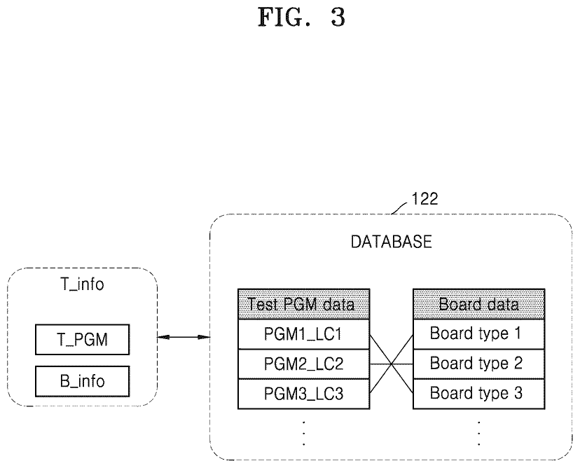

FIG. 3 is a diagram illustrating a matching process according to some implementations.

Referring to FIGS. 1 and 3, the test device 100 may receive the test information T_info and perform a matching operation. The test information T_info may include information T_PGM on a test program to be executed by the test device 100 and information B_info on a board. Conditions under which the semiconductor module is loaded on the board may vary according to the test program, and loading conditions for each program may be stored in the database 122. For example, the test program data stored in the database 122 may include a first loading condition PGM1_LC1 corresponding to a first test program, a second loading condition PGM2_LC2 corresponding to a second test program, and a third loading condition PGM3_LC3 corresponding to a third test program. For example, the first test program may be a program for testing the operating temperature of the semiconductor module to be loaded, and the loading condition accordingly may be the first loading condition PGM1_LC1. As another example, the second test program may be a program for testing the timing of the semiconductor module to be loaded, and the loading condition accordingly may be the second loading condition PGM2_LC2. The board mounted on the test device 100 may be of various types, and the structure of the board, the location of the slot, and/or the arrangement of the slot may vary depending on the type of the board, and information on the type of the board (e.g., location information of the slots) may be stored in the database 122. For example, the board data stored in the database 122 may include data regarding a first board type, a second board type, and a third board type. In some implementations, the database 122 stores information on at least one of the arrangement of slots and the locations of the slots corresponding to each board type (e.g., the information may be stored in the form of a unique number of the slot or coordinate information on the location of the slot). Conditions for loading the semiconductor module may vary according to the test program data and the board data, and the processor 110 may generate the condition as a matching result and use the generated condition to select a target slot.

Accordingly, the test device 100 may flexibly respond to various test environments by constructing or incorporating various test programs and various board types as a database and may effectively automate the test process.

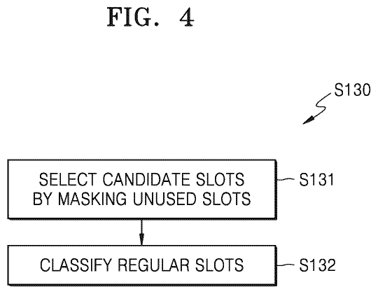

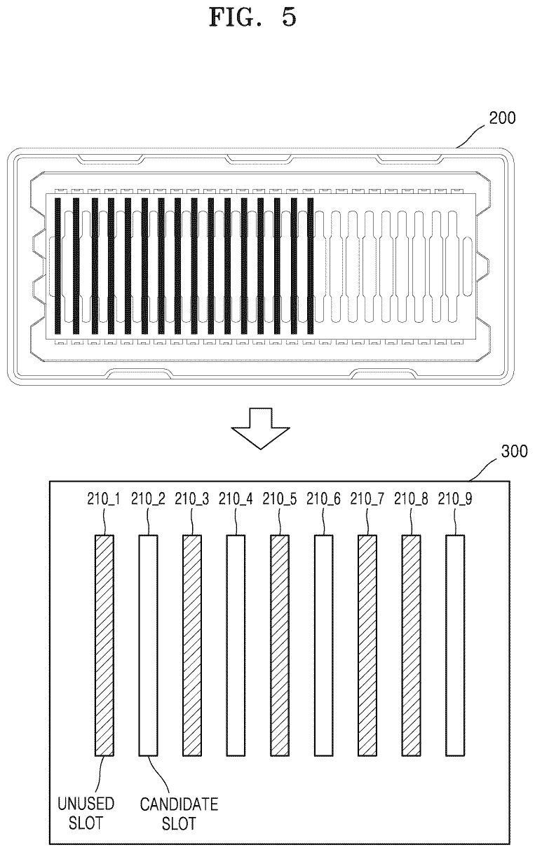

FIG. 4 is a flowchart illustrating a simulation operation according to some implementations. FIG. 5 is a diagram associated with the simulation operation.

Referring to FIGS. 2, 4, and 5, the loading simulation operation S130 may include operations S131 and S132. The test device 100 may transfer, to a board 300, at least one semiconductor module from a tray 200 on which a plurality of semiconductor modules are loaded. The board 300 mounted on the test device 100 may include a plurality of slots 210_1 to 210_9, and the processor 110 may select candidate slots to be a target slot from among the plurality of slots 210_1 to 210_9 through simulation.

In operation S131, based on a result of the matching, the processor 110 may select candidate slots by masking unused slots from among slots of the board 300. As an example, odd-numbered slots may be unused slots as a result of matching. In this case, the processor 110 may exclude odd-numbered slots from the candidate slots by masking the odd-numbered slots in the simulation operation for target slot selection. As another example, as shown in FIG. 5, in the result of the matching, the first slot 210_1, the third slot 210_3, the fifth slot 210_5, the seventh slot 210_7, and the eighth slot 210_8 may be determined to be unused slots, and the processor 110 may mask the unused slots. Accordingly, the second slot 210_2, the fourth slot 210_4, the sixth slot 210_6, and the ninth slot 210_9 may be selected as the candidate slots.

In operation S132, the processor 110 may classify regular slots from among the candidate slots. In some implementations, when performing a loading operation, the processor 110 may determine target slots based on the regular slots from among the candidate slots. For example, as illustrated in FIG. 5, regular slots (e.g., slots having a regular arrangement among candidate slots) among the candidate slots 210_2, 210_4, 210_6, and 210_9 may be the second slot 210_2, the fourth slot 210_4, and the sixth slot 210_6. In some implementations, the processor 110 may determine a target slot among the regular slots 210_2, 210_4, and 210_6 based on the number of semiconductor modules currently operable, that is, pickable. For example, when there are two operable semiconductor modules, two of the regular slots 210_2, 210_4, and 210_6 may be determined to be target slots. In addition, the ninth slot 210_9, which is a candidate slot not classified into the previous regular slots 210_2, 210_4, and 210_6, may be designated as a target slot in a subsequent loading operation.

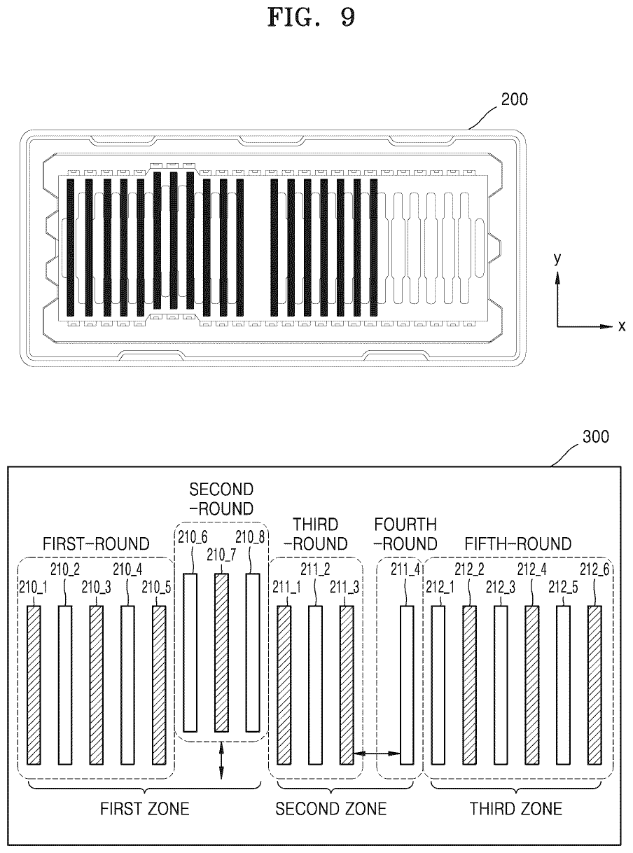

A set of regular slots can be slots that are aligned with one another in a direction of extension of the slots, e.g., as described with respect to FIG. 9.

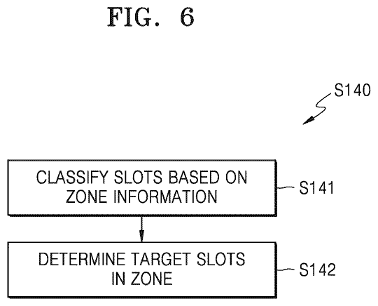

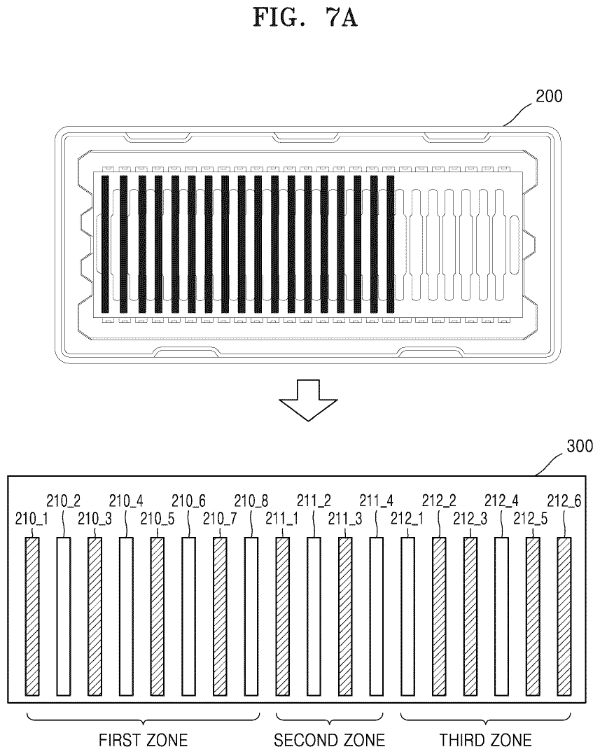

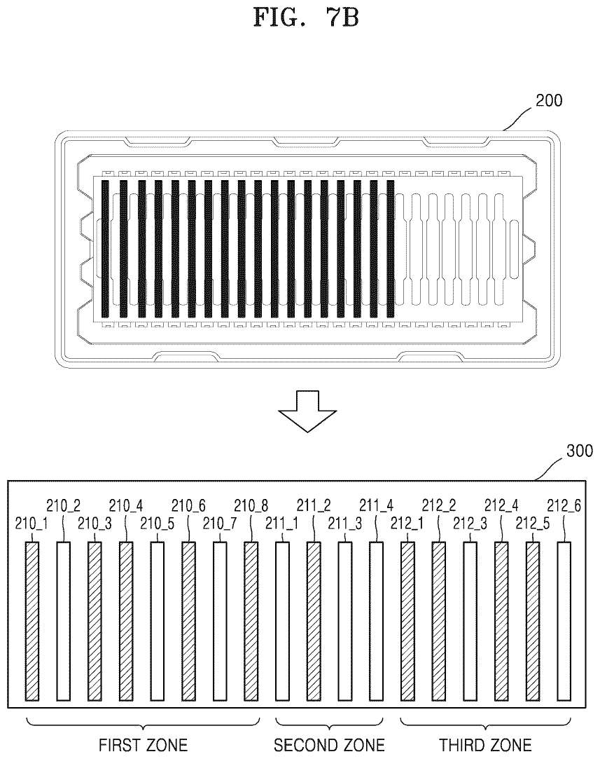

FIG. 6 is a flowchart illustrating a method of selecting a target slot, according to some implementations, and FIGS. 7A and 7B are diagrams associated with the method.

Referring to FIGS. 2 and 6, the target slot selection operation S140 may include operations S141 and S142. The board data stored in the database 122 may include zone information for classifying slots according to a board type, and the processor 110 may determine a target slot based on the zone information.

In operation S141, the processor 110 may classify the slots of the board 300 based on the zone information. When selecting a target slot from among candidate slots, the processor 110 may select a target slot for each zone. As an example, as illustrated in FIG. 7A, a first zone of the board 300 may include a plurality of first slots 210_1 to 210_8, a second zone may include a plurality of second slots 211_1 to 211_4, and a third zone may include a plurality of third slots 212_1 to 212_6. For example, as a result of matching, odd-numbered slots in the first zone and the second zone may be determined to be unused slots, and even-numbered slots may be selected as candidate slots. The processor 110 may classify the candidate slots according to the zones in the board 300.

In operation S142, the processor 110 may slots within the same zone to be used as target slots for a round of loading. For example, the candidate slots 210_2, 210_4, 210_6, 210_8 in the first zone and the candidate slots 211_2, and 211_4 in the second zone are all regular slots, but the processor 110 may select a target slot by dividing the regular slots according to the zones when performing one loading operation. For example, the candidate slot 210_8 and the candidate slot 211_2 are slots having a regular arrangement, but the processor 110 may determine the two candidate slots as target slots of different rounds. For each round of loading, the target slots can be selected from within a single zone.

For example, when the number of operable semiconductor modules is 3, the processor 110 may select candidate slots 210_2, 210_4, and 210_6 as target slots in the first-round loading operation and may select only the candidate slot 210_8 as the target slot in the second-round loading operation. The candidate slot 211_2 may be selected as a target slot in a subsequent loading operation. Similarly, since the candidate slot 211_4 and the candidate slot 212_1 are slots belonging to different zones, the candidate slot 211_4 and the candidate slot 212_1 may be selected as target slots in different rounds, respectively. As a result of matching, the slot 212_1 and the slot 212_4 from among the slots in the third zone may be candidate slots, and the two slots may be determined as slots having a regular arrangement. Thus, the two slots may be target slots in the same round.

As another example, as a result of matching, candidate slots may appear in each zone of the board 300 as shown in FIG. 7B. For example, when the test program in FIG. 7B is different from the test program in FIG. 7A, the candidate slots of FIG. 7B may be selected differently from those of FIG. 7A. As described above, the processor 110 may select target slots from among regular slots, and thus the candidate slot 210_2 may be selected as the first-round target slot and the candidate slots 210_5 and 210_7 may be selected as the second-round target slots. However, implementations are not limited thereto, and the selection of the target slots may be made in various ways. For example, target slots in a round need not be regularly-spaced with respect to one another. For example, the candidate slots 210_2, 210_5, and 210_7 may be selected as target slots of the same round. For example, as described below, a plurality of hands of the gripper of the test device 100 may be individually controlled and pitched, and may be pitched to correspond to each of the candidate slots 210_2, 210_5, and 210_7.

As an example, although the candidate slot 210_7 and the candidate slot 211_1 are regular slots, since they are slots in different zones, the processor 110 may determine the two candidate slots as target slots of different rounds. The processor 110 may select target slots from among regular slots in the second zone, and thus the candidate slot 211_1 may be selected as a target slot of the third-round and the candidate slots 211_3 and 211_4 may be selected as target slots of the fourth-round. However, implementations are not limited thereto, and the selection of the target slots may be made in various ways. Since the plurality of hands of the gripper may be individually controlled and pitched, the candidate slots 211_1, 211_3, and 211_4 may be selected as target slots of the same round.

Furthermore, the slot 212_3 and the slot 212_6 from among the slots in the third zone may be candidate slots, and the two slots may be determined as regular slots. Thus, the two slots may be target slots in the same round.

Accordingly, in some implementations, the test device 100 may flexibly respond to various test environments and perform the loading operation more efficiently by constructing information on zones according to the type of board as a database and using the information in a loading operation.

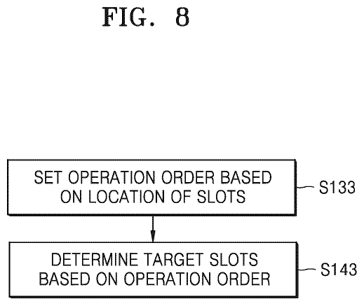

FIGS. 8 and 9 relate to a method of determining a target slot, according to some implementations.

Referring to FIGS. 8 and 9, the loading simulation operation S130 of FIG. 4 may include operation S133 and the target slot selection operation S140 of FIG. 6 may include operation S143. The board data stored in the database 122 may include information on the structure of the board 300 (e.g., the locations of the slots) according to the board type, and the processor 110 may determine a target slot based on the locations of the slots included in the board 300.

In operation S133, the processor 110 may set a loading operation order based on the locations of the slots, and in operation S143, the processor 110 may determine a target slot according to the operation order.

For example, as illustrated in FIG. 9, the slots 210_1 to 210_8 are included in the same first zone but may be selected as target slots of different rounds. As an example, relative locations between slots may vary according to the type and/or structure of the board 300. For example, the candidate slots 210_2, 210_4, 210_6, and 210_8 in the first zone are regular slots having regularity (e.g., regular slots aligned with one another in the second direction y), but the slots 210_6 to 210_8 may be spaced apart from the slots 210_1 to 210_5 by a predetermined distance in the second direction y, e.g., offset from the slots 210_1 to 210_5 in the second direction y. Accordingly, the processor 110 may perform loading operations on the slots 210_6 to 210_8 and the slots 210_1 to 210_5 in different rounds, for example, determine the candidate slots 210_2 and 210_4 as the first-round target slots and the candidate slots 210_6 and 210_8 as the second-round target slots.

In addition, the slots 211_1 to 211_4 are included in the same second zone but may be selected as target slots of different rounds. For example, the candidate slots 211_2 and 211_4 in the second zone are regular slots, but the slot 211_4 may have a structure spaced further apart by a predetermined distance than the distance between two adjacent slots from among the slots 211_1 to 211_3 in the first direction x. Accordingly, the processor 110 may perform loading operations on the slot 211_4 and the slots 211_1 to 211_3 in different rounds, for example, determine the candidate slots 211_1 to 211_3 as the target slots of the third-round and the candidate slot 211_4 as the target slot of the fourth-round. Since the slots 212_1 to 212_6 are included in the same third zone and do not have a structure in which the slots 212_1 to 212_6 are spaced apart from each other, the processor 110 may select the regular candidate slots 212_1, 212_3, and 212_5 as target slots of the same round.

Accordingly, the test device 100 may flexibly respond to various test environments and perform the loading operation more efficiently by constructing information on structures according to the type of board as a database and using the information in a loading operation.

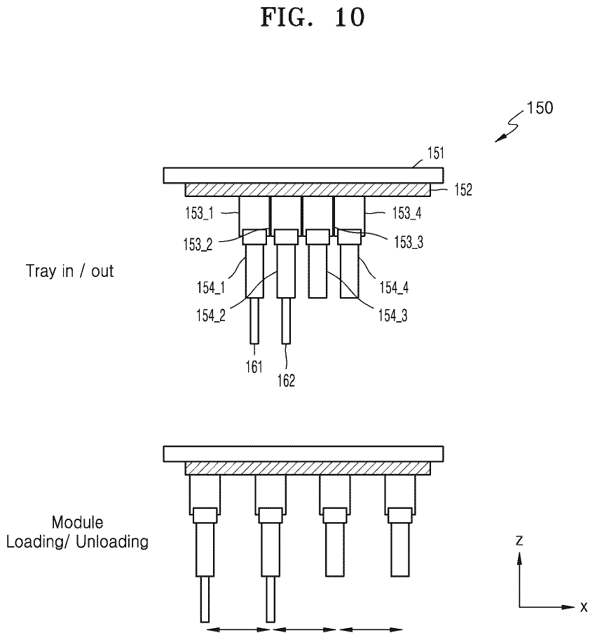

FIG. 10 is a side view of a gripper according to some implementations.

Referring to FIG. 10, a gripper 150 of the test device 100 may include a frame 151, a ball screw 152, and a plurality of hands 153_1 to 153_4. The frame 151 of the gripper 150 may be connected to the plurality of hands 153_1 to 153_4 and, as an example, may be connected to a rail or a robot arm to move the gripper 150. In some implementations, the ball screw 152 may pitch the plurality of hands 153_1 to 153_4. For example, the processor 110 may control the ball screw 152 to simultaneously pitch the intervals of the plurality of hands 153_1 to 153_4, thereby moving the hand holding the semiconductor module among the plurality of hands 153_1 to 153_4 to correspond to the locations of the target slots. In some implementations, the plurality of hands 153_1 to 153_4 of the gripper 150 may be connected in an X-rack format. For example, the gripper 150 may simultaneously pitch the intervals of the plurality of hands 153_1 to 153_4 connected in the X-rack format through the ball screw 152. In addition, in some implementations, the gripper 150 may be raised or lowered by the robot arm to pick, load, or unload the semiconductor module. For example, the robot arm may move the gripper 150 in a third direction z to pick the semiconductor module loaded on the tray through the hands of the gripper 150 or to load the transferred semiconductor module in the target slot (for example, the gripper may descend in the third direction z). Alternatively, or in addition, the robot arm may move the gripper 150 in the third direction z to transfer the semiconductor module picked by the hand of the gripper 150 or after loading the semiconductor module in the target slot (e.g., the gripper may rise in the third direction z.

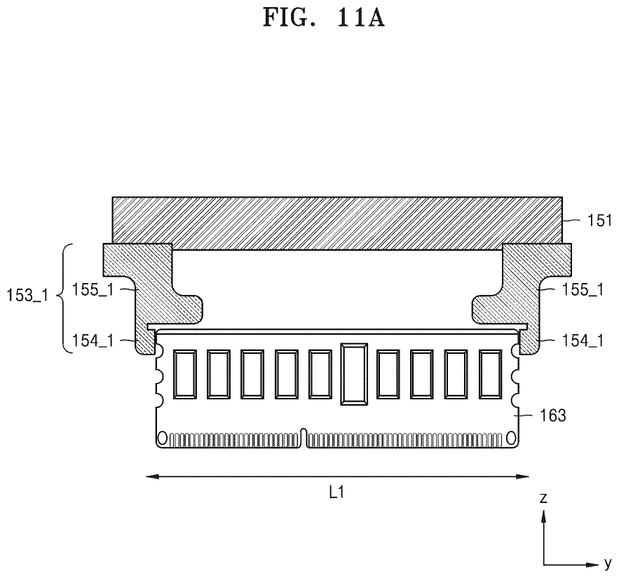

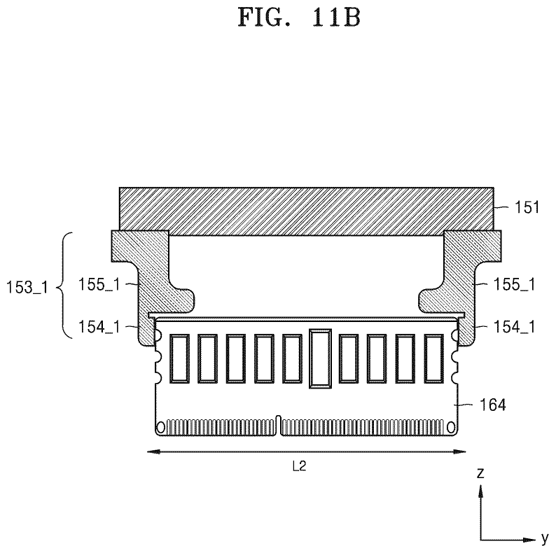

In some implementations, the plurality of hands 153_1 to 153_4 may include holders 154_1 to 154_4 for holding the semiconductor modules, respectively. The holders 154_1 to 154_4 may be formed in pairs and may be spaced apart from each other to hold the semiconductor modules, respectively, as described with respect to FIGS. 11A-11B. As described above, the gripper 150 may pitch each of the plurality of hands 153_1 to 153_4 to load the picked semiconductor modules in the target slots or unload the semiconductor modules from the target slots through the ball screw 152. Subsequently, the holders 154_1 to 154_4 of the plurality of hands 153_1 to 153_4 may be spaced apart from each other by the gripper 150 to hold the semiconductor modules. For example, the gripper 150 may move the plurality of hands 153_1 to 153_4 connected to the ball screw 152 in the first direction x to correspond to the target slots, respectively, and the distance moving in the first direction x may be variously implemented.

In some implementations, as described above with reference to FIG. 9, the processor 110 may transfer the semiconductor modules by pitching the plurality of hands 153_1 to 153_4 of the gripper 150 to correspond to the locations of the slots. For example, as described above, the processor 110 may determine the candidate slots 210_2 and 210_4 of FIG. 9 as the first-round target slots based on the locations of the slots, and thus the gripper 150 may pick two semiconductor modules to be transferred in the first-round loading operation in the tray 200. For example, the using 150 may pick a first semiconductor module 161 and a second semiconductor module 162 through the first hand 153_1 and the second hand 153_2, respectively. The first hand 153_1 may space the first holder 154_1 apart to hold the first semiconductor module 161, the second hand 153_2 may space the second holder 154_2 apart to hold the second semiconductor module 162. The gripper 150 may align the first hand 153_1 with the first semiconductor module 161 to pick the first semiconductor module 161, and may align the second hand 153_2 with the second semiconductor module 162 to pick the second semiconductor module 162. The gripper 150 may transfer the picked semiconductor modules to the board 300. In this case, the processor 110 may pitch the first hand 153_1 and the second hand 153_2 to correspond to locations of the candidate slots 210_2 and 210_4 determined to be target slots, respectively, using the ball screw 152. Thereafter, the processor 110 may lower the gripper 150 through the robot arm, and the first semiconductor module 161 and the second semiconductor module 162 may be mounted in the target slots, respectively.

Accordingly, the test device 100 may provide an automation process that flexibly responds to various types of boards and various slot structures by loading semiconductor modules through the gripper capable of adjusting the pitching distances between hands.

FIGS. 11A and 11B are front views of a gripper according to some implementations.

Referring to FIGS. 10, 11A, and 11B, the first hand 153_1 of the gripper 150 may be connected to the frame 151 and may include a pair of first bodies 155_1 and a pair of first holders 154_1. As described above, the plurality of hands 153_1 to 153_4 may be connected to the frame 151 in an X-rack format, and the spacing between two adjacent hands among the plurality of hands 153_1 to 153_4 may be pitched using the ball screw 152. Hereinafter, for convenience of description, a first hand 153_1 will be described. The following description may be applied to all of the plurality of hands 153_1 to 153_4, and it will be understood that grippers within the scope of this disclosure may include other numbers of hands.

The first hand 153_1 of the gripper 150 may be moved in the third direction z by the robot arm to pick a semiconductor module or load or unload a semiconductor module on or from the slot. In some implementations, as illustrated in FIG. 11A, the first bodies 155_1 of the first hand 153_1 may be paired and spaced apart from each other in the second direction y to hold the third semiconductor module 163. For example, the gripper 150 may space the first bodies 155_1 apart from each other in the second direction y to correspond to the first width L1 in the second direction y of the third semiconductor module 163. The first holders 154_1 may be connected to the first bodies 155_1, respectively, and after the first bodies 155_1 are spaced apart from each other to correspond to the first width L1 of the third semiconductor module 163, the first holders 154_1 may hold the third semiconductor module 163. In some other implementations, as illustrated in FIG. 11B, the first bodies 155_1 of the first hand 153_1 may be paired and spaced apart from each other in the second direction y to hold the fourth semiconductor module 164. For example, the gripper 150 may space the first bodies 155_1 apart from each other in the second direction y to correspond to the second width L2 in the second direction y of the fourth semiconductor module 164. As an example, the third semiconductor module 163 may be a memory mounted on a server, a desktop, or the like, and the fourth semiconductor module 164 may be a memory mounted on a notebook or the like. The second width L2 of the fourth semiconductor module 164 may be less than the first width L1 of the third semiconductor module 163, and thus the width at which the gripper 150 spaces the first bodies 155_1 apart from each other to hold the fourth semiconductor module 164 may be less than the case for holding the third semiconductor module 163. For example, the width at which the first bodies 155_1 are spaced apart in the second direction y may be adjusted to flexibly correspond to the widths of various semiconductor modules. For example, the width of the semiconductor module in the second direction y may be variously implemented according to the type of the semiconductor module, the width at which the first bodies 155_1 are spaced may be variously adjusted correspondingly, and the gripper 150 may hold the semiconductor modules of various lengths by spacing the first bodies 155_1 in the second direction y. In some implementations, as described above, information on the semiconductor modules may also be stored in the database (e.g., database 122), and the processor 110 may control the gripper 150 by receiving, from the database, information on the semiconductor modules to be loaded on the board.

Accordingly, in some implementations, the test device 100 may not only respond to various structures of the boards by controlling the spacing of each hand but also to semiconductor modules of various lengths by controlling the widths of the spaced bodies connected to the holder holding the semiconductor module.

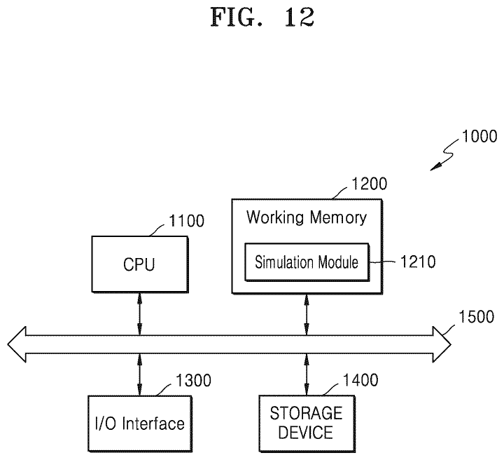

FIG. 12 is a block diagram illustrating a test system according to some implementations.

Referring to FIGS. 1 and 12, a test system 1000 may include a central processing unit (CPU) 1100, which is an example of a processor, a working memory (or memory) 1200, an input/output (I/O) interface 1300, a storage device 1400, and a system bus 1500. Here, the test system 1000 may be provided as a dedicated device for testing the test device but may also be a system for mounting a memory module to a device.

The CPU 1100 may execute software (application programs, an operating system, device drivers, and the like) to be executed in the test system 1000. The CPU 1100 may correspond to the processor 110 of FIG. 1. For example, the CPU 1100 may execute an operating system (OS) loaded on the working memory 1200. The CPU 1100 may execute various application programs or modules to be driven based on the OS. For example, the CPU 1100 may drive a simulation module 1210 that performs a simulation operation loaded in the working memory 1200, and the simulation module 1210 may be a module for selecting a slot in which the semiconductor module is loaded to automate the loading operation of the semiconductor module.

An OS or application programs may be loaded on the working memory 1200. All operations of the test system 1000 may be supported by the OS. Likewise, application programs for automation of tests (e.g., the simulation module 1210) may be loaded into the working memory 1200. The working memory 1200 may be a volatile memory such as static random access memory (SRAM) or dynamic random access memory (DRAM), or a nonvolatile memory such as phase change random access memory (PRAM), magnetic RAM (MRAM), resistive RAM (ReRAM), ferroelectric RAM (FRAM), or flash memory.

The I/O interface 1300 may control user input and output from user interface devices. For example, the I/O interface 1300 may be provided with an output device such as a monitor to display the progress and test results of the test operation of the test system 1000.

The storage device 1400 may be provided as a storage medium of the test system 1000. The storage device 1400 may store application programs, an OS, images, and various types of data. The storage device 1400 may correspond to the memory 120 of FIG. 1. In some implementations, the storage device 1400 includes a database, and data on various test programs and data on types of boards may be stored in the database. The CPU 1100 may determine a condition under which the semiconductor modules are loaded by matching test information received from the outside to information stored in the database. In this way, the test system 1000 may flexibly respond to various test environments and may effectively automate a test process by constructing various pieces of data as a database.

The storage device 1400 may be provided as a memory card (e.g., a multi-media card (MMC), an embedded MMC (eMMC), a secure digital (SD) card, a MicroSD card, etc.) or a hard disk drive (HDD). The storage device 1400 may include a NAND-type flash memory having a large storage capacity. Alternatively, the storage device 1400 may include a next-generation nonvolatile memory such as PRAM, MRAM, ReRAM, FRAM, or the like, or flash memory.

The system bus 1500 may be provided as an interconnector for providing a network inside the test system 1000. The CPU 1100, the working memory 1200, the I/O interface 1300, and the storage device 1400 may be electrically connected through the system bus 1500 and may exchange data with each other. However, the configuration of the system bus 1500 is not limited to the above description and may further include arbitrary means for efficient management.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been shown and described, it will be understood that various changes in form and details may be made therein without departing from the spirit and scope of the disclosure.

What is claimed is:

1. A method of operating a test device for testing a semiconductor module, the method comprising:
receiving test information;
matching test program data and board data stored in a database to the test information;
selecting at least one target slot from among slots of a board based on a result of the matching;
picking at least one semiconductor module using a plurality of hands of a gripper of the test device, wherein a number of the at least one semiconductor module matches a number of the at least one target slot; and
loading the at least one semiconductor module into the at least one target slot of the board using the gripper.

2. The method of claim 1, wherein selecting the at least one target slot comprises:
selecting candidate slots by distinguishing unused slots among the slots of the board; and
classifying regular slots from among the candidate slots.

3. The method of claim 2, wherein selecting the at least one target slot comprises selecting the at least one target slot from among the regular slots based on a number of operable semiconductor modules.

4. The method of claim 2, wherein selecting the at least one target slot comprises selecting the at least one target slot from among the regular slots based on zone information included in the board data.

5. The method of claim 2, wherein selecting the at least one target slot comprises:
setting an operation order based on locations of the slots of the board, and selecting the at least one target slot from among the regular slots according to the operation order.

6. The method of claim 1, wherein picking the at least one semiconductor module comprises pitching the plurality of hands to correspond to the at least one target slot.

7. The method of claim 6, wherein each of the plurality of hands is individually controlled to pitch the plurality of hands.

8. The method of claim 1, wherein:
the database further comprises module information characterizing the at least one semiconductor module, and
picking the at least one semiconductor module comprises controlling, based on a length of the at least one semiconductor module as indicated by the module information, a width at which holders of the plurality of hands are spaced to hold the at least one semiconductor module.

9. The method of claim 1, wherein the test program data comprises information indicating loading conditions based on a test program corresponding to a purpose of testing, and the board data comprises location information of slots based on a type of the board.

10. The method of claim 1, wherein the test information comprises information indicating a test program corresponding to a test purpose and information indicating a type of the board.

11. A device for semiconductor module testing, the device comprising:
a gripper;
at least one processor; and
a memory including a database in which test program data and board data are stored, wherein the at least one processor is configured to:
match received test information to the test program data and the board data;
select at least one target slot from among slots of a board based on a result of the matching;
control the gripper based on the at least one target slot;
pick at least one semiconductor module using a plurality of hands of the gripper, wherein a number of the at least one semiconductor module matches a number of the at least one target slot; and
load the at least one semiconductor module into the at least one target slot of the board.

12. The device of claim 11, wherein the at least one processor is configured to:
select candidate slots by distinguishing unused slots among the slots of the board; and
classify regular slots from among the candidate slots.

13. The device of claim 12, wherein the at least one processor is configured to select the at least one target slot from among the regular slots based on zone information included in the board data.

14. The device of claim 12, wherein the at least one processor is configured to:
set an operation order based on positions of the regular slots; and
select the at least one target slot from among the regular slots based on the operation order.

15. The device of claim 11, wherein the gripper is configured to pitch the plurality of hands to correspond to the at least one target slot.

16. The device of claim 11, wherein:
the database further comprises module information characterizing the at least one semiconductor module, and
the gripper is configured to control, according to a length of the at least one semiconductor module as indicated by the module information, a width at which holders of the plurality of hands are spaced to hold the semiconductor module.

17. A method of operating a test device for loading a semiconductor module, the method comprising:
receiving type data characterizing a target board on which the semiconductor module is to be loaded;
matching board data to the type data, wherein the board data includes location information of slots of the target board, and wherein the board data is stored in a database;
selecting at least one target slot from among the slots of the target board based on a result of the matching;
generating slot data characterizing the at least one target slot;
controlling, based on the slot data, a gripper of the test device, the gripper including a plurality of hands; and
loading the semiconductor module into a first slot of the at least one target slot using the gripper.

18. The method of claim 17, wherein selecting the at least one target slot comprises selecting the at least one target slot from among the slots of the target board based on zone information included in the board data.

19. The method of claim 17, wherein each of the plurality of hands is individually controlled, and wherein controlling the gripper comprises pitching the plurality of hands to correspond to the at least one target slot.

20. The method of claim 17, wherein the database further comprises module information characterizing the semiconductor module, and wherein the method further comprises controlling a width at which holders of the plurality of hands are spaced to hold the semiconductor module, based on a length of the semiconductor module as indicated by the module information.
